(19) United States
(12) Patent Application Publication
(10) Pub. No.: US 2020/0078884 A1
(43) Pub. Date: Mar. 12, 2020

(54) LASER PLANARIZATION WITH IN-SITU SURFACE TOPOGRAPHY CONTROL AND METHOD OF PLANARIZATION

(71) Applicant: Intel Corporation, Santa Clara, CA (US)

(72) Inventors: Bai Nie, Chandler, AZ (US); Yonggang Li, Chandler, AZ (US)

(21) Appl. No.: 16/124,292

(22) Filed: Sep. 7, 2018

(51) Int. Cl. B23K 26/352; H05K 3/00; C23C 14/02; C23C 18/18

(52) U.S. Cl. CPC B23K 26/3576; H05K 3/0032; H05K 2203/0195; C23C 18/18; H05K 2203/107; C23C 14/022

(57) ABSTRACT

A system and method of planarizing a layer are disclosed. Topography of the layer is measured to produce a topographic map, which is then digitized into blocks of that indicate different thickness variation. Laser conditions are assigned for each block, a laser steered to planarization blocks where material is to be removed, and the material ablated at each planarization block. In-situ monitoring of the surface profile provides feedback to adjust the laser conditions during planarization. When depth control is used, the laser is focused at a focal plane and has a focal depth beyond which no material is ablated and the laser is steered across the entire layer. A thin metal layer of higher ablation threshold than the dielectric layer formed over the layer provides added selectivity, with the laser conditions changed after ablation of the metal layer. Otherwise, planarization is limited to the planarization blocks.

### TECHNICAL FIELD

This disclosure relates generally to electronic device processing. Some embodiments are related to a planarization process used during electronic device processing. Some embodiments are related to laser planarization with in-situ control.

### BACKGROUND

Electronic devices continue to permeate every aspect of daily life. Among the many types of electronic devices, smartphones and other electronic communication devices that rely on microelectronics continue to grow, as does the desire for increased processing power. The complexity and density of the circuitry also continues to grow. This is problematic for a number of reasons that include operational issues such as problems with power dissipation and current leakage through dielectric layers as well as manufacturing issues, such as when excessive variations in the thickness of different layers exist.

In particular, variations in the thickness of the substrate or interposer layer may cause substantial variations in the thickness of an overlying copper (Cu) layer. This may cause a laminated dielectric layer to have a thickness variation conformal to the underlying Cu density underneath. Planarization is needed to reduce such variation, and current Chemo-Mechanical Polishing (CMP)-based planarization has its capability limit. Eventually, this may result in warping of the structure, leading to poor electrical contact between a substrate and die. Planarization may be used to reduce these thickness variations but is limited.

### BRIEF DESCRIPTION OF THE DRAWINGS

FIG. 1 illustrates a laser planarization system in accordance with some embodiments.

FIG. 2 illustrates a method of planarization in accordance with some embodiments.

FIG. 3A illustrates a dielectric topography profile in accordance with some embodiments; FIG. 3B illustrates a digitization of the dielectric topography profile of FIG. 3A in accordance with some embodiments.

FIGS. 4A-4D illustrate cross-sectional views of a method of planarization according to some embodiments.

FIGS. 5A-5B illustrate cross-sectional views of another method of planarization according to some embodiments.

FIGS. 6A-6D illustrate cross-sectional views of another method of planarization according to some embodiments.

FIG. 7 illustrates skiving in accordance with some embodiments.

FIG. 8 illustrates a method of planarization in accordance with some embodiments.

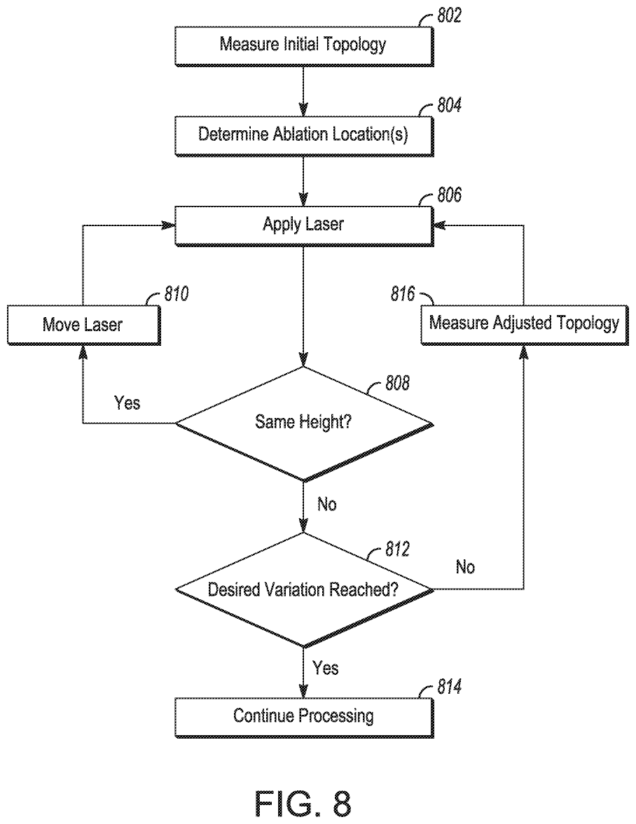

FIG. 9 illustrates a system level diagram for devices associated with the laser planarization process by the methods described herein.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation. In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous. The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

As used herein, the term “module” may refer to, be part of, or include an ASIC, an electronic circuit, a SOC, a processor (shared, dedicated, or group), and/or memory (shared, dedicated, or group) that execute one or more software or firmware programs, a combinational logic circuit, and/or other suitable components that provide the described functionality.

As above, planarization of metal and organic layers during fabrication of a semiconductor package is desirable to provide a substantially level surface on which a succeeding layer is formed. Typically, chemical mechanical polish (CMP) or fly cutting may be used for planarization. In CMP, the surface to be planarized is mechanically applied to an abrasive chemical slurry by rotating the surface on a polishing pad impregnated with the slurry. The CMP tools assume that the bottom side surface is flat, the top side topology is ideal and no in-situ end point control is desired. However, the bottom topology, which is unavoidable for most organic substrate panels, is likely to transfer to some extent to the top side. Even when the bottom side is substantially flat (within a tolerable variance), the planarization capability is highly dependent on the top side topology, notably for planarization of a uniform material where no selectivity exists. Nor does CMP have an effective method to detect and control the end point in-situ. Moreover, the high cost of CMP is still prohibitive to panel level packaging applications.

In fly cutting, a cutting bit with a sharp edge is swept across the surface to be planarized. Similar to the above, for adequate fly cutting a flat bottom side surface is desired to ensure good planarization. Fly cutting also runs into significant barriers for planarization of the dielectric or solder resist materials, as the high amount of silica fillers causes excessive wear and tear on the fly cutting tool.

The above techniques may be insufficient for current processing used for high-density circuitry. Such processing, while dependent on feature size for example (e.g., 2 μm×2 μm), may be able to operate with layers having thickness variations of a few microns, e.g., less than about 5 microns. This level of control may be difficult to obtain through use of CMP or fly cutting alone. For example, organic packages currently carry thickness variations of 40-60 μm or more, making it likely that at least some bumps of a 20-30 mm die having hundreds or thousands of bumps for connection to the substrate being unable to contact the underlying package. Consequently, these techniques may be substituted or supplemented through the use of laser removal of material.

In particular, a laser material removal-based planarization tool may be used in conjunction with in-situ panel level topology monitoring and a feedback loop. The laser may be used to selectively remove high topology portions of the panel (i.e., localized portions of the panel with large thickness variations) layer-by-layer to achieve planarization. With in-situ monitoring and an instantaneous feedback loop, laser planarization can be controlled with sub-micron resolution in depth. This method can be used to planarize various organic materials, such as polymers and acrylics. Other types of layers (e.g., metallization layers) may be planarized, however, laser planarization of organic materials may be more controllable. The process can be used to planarize a panel, or any sub-panel form factor, in both free standing status and bottom confined status. In addition, the thickness of the panel may be dynamically monitored with precise end point control. In some embodiments, both organic substrates as well as organic layers during fabrication may be planarized. Organic layers up to the first level interconnect (FLI) may be planarized.

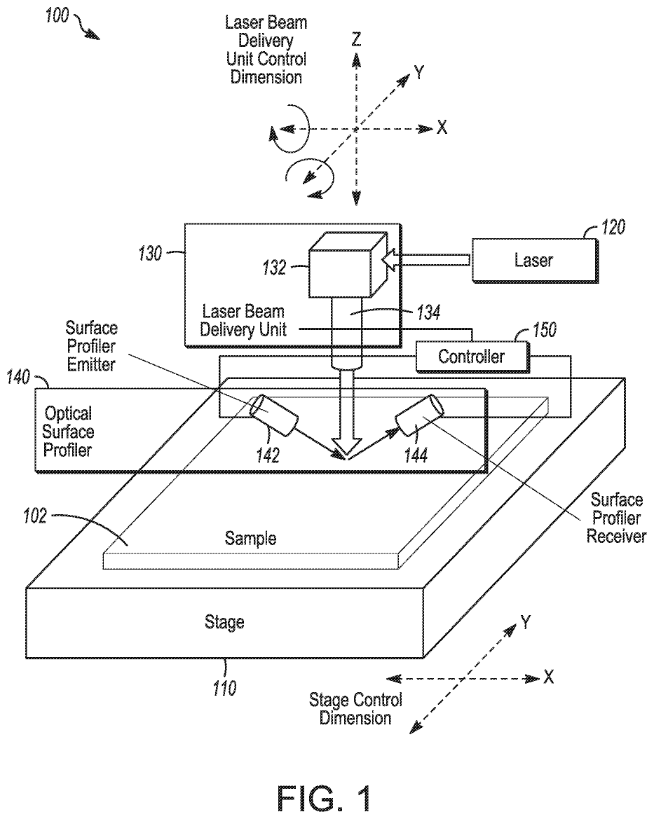

FIG. 1 illustrates a laser planarization system in accordance with some embodiments. The laser planarization system 100 may contain several components, including a high power laser system 120 (referred to herein as a laser), a laser beam delivery unit 130, an optical surface profiler 140, and a feedback loop control system (controller) 150. The laser 120 may contain a laser control system and may produce, for example, a UV or deep UV laser for ablation of the organic (or other) material.

A panel 102 to be planarized may be disposed on a sample stage 110. The stage 110 may retain the panel 102 using vacuum chucking. A switch may be used to flexibly activate or deactivate the vacuum to adhere the panel 102 to the stage 110. The stage 110 may be adjustable in the XY direction, as shown.

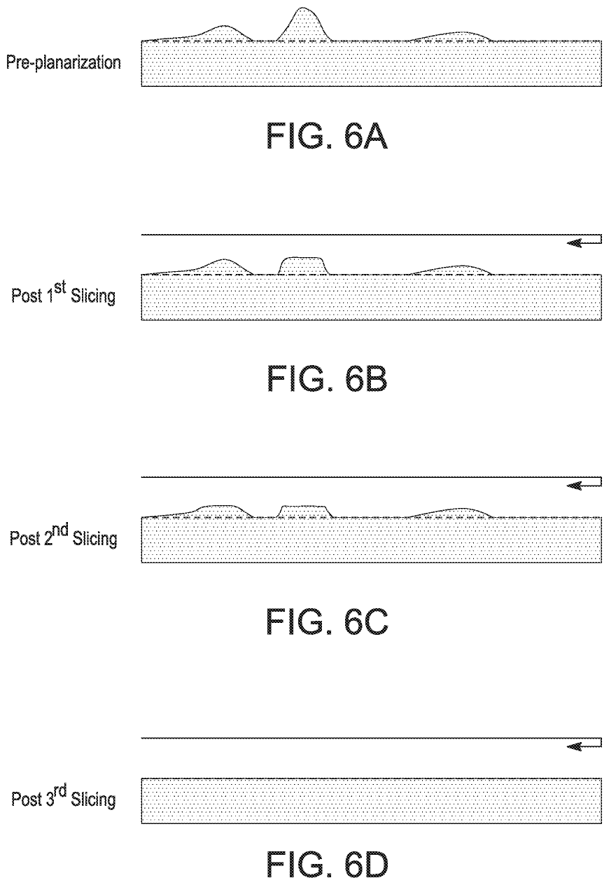

The laser beam delivery unit 130 may contain a Galvano scanner system 132 and a focusing optical system 134. The Galvano scanner system may contain multiple galvanometer scan mirrors to direct the laser beam to any position in the field of view. The scan mirrors may each be for a different axis. Thus, 2 mirrors may be used for scanning in the XY direction. The focusing optical system 134 may be used for adjustment in the Z direction. The Galvano scanner system 132 may be used to enable the laser beam delivery unit 130 to scan in straight lines (as shown in the example of FIG. 6) or may be used for arbitrary (non-straight line) scans. The spot size of the laser delivered may be, for example, between about 10 and 100 μm with a fluence of about 0.1-1.0 J/cm².

In operation, the laser beam from the laser 120 may impinge on the laser beam delivery unit 130. The laser beam delivery unit 130 may be mounted on a 3D stage system that can scan the laser beam across the entire sample 102 with or without moving the sample stage 110. The laser beam delivery unit 130 may be used to ablate material on the panel, planarizing areas of the panel with topology (thicknesses) that vary more than a maximum threshold. To further enhance the processing flexibility, a rotation control can be added to the laser beam delivery unit 130 to enable tilted beam processing (rotation from the z axis shown in FIG. 1).

In some embodiments, the laser beam delivery unit 130 may be stationary, with only the Galvano scanner system 132 steering the laser beam to impinge on the location of the panel 102 from which material is to be removed. Alternatively, if the laser beam delivery unit 130 moves, the laser beam may be adjusted using mirrors external to the laser beam delivery unit 130 (not shown) to impinge on the same entry point of the laser beam delivery unit 130 independent of the location of the laser beam delivery unit 130 and the Galvano scanner system 132 steering the laser beam to impinge on the location of the panel 102 from which material is to be removed. If the laser beam delivery unit 130 moves, the laser beam delivery unit 130 may be disposed at a location vertically aligned with the material to be ablated.

The optical surface profiler 140 may contain a surface profiler emitter 142 and a surface profiler receiver 144. The emitter 142 may be a photoemitter, for example, a low power laser or light emitting diode (LED). The receiver 144 may be, for example, a photodiode. The wavelength range used by the optical surface profiler 140 may depend on, for example, the feature size of the panel 102. The optical surface profiler 140 can be either confocal or non-confocal (wide field). A confocal surface profiler has a co-axis setup in which out of focus light is removed using a spatial pinhole and the overall excitation energy to form a good image reduced accordingly.

The optical surface profiler 140 may be used during a pre-planarization profile scan to determine the surface topology profile of the panel 102. The optical surface profiler 140 may also be used during in-situ monitoring of the profile during the planarization process to adjust laser parameters. The optical surface profiler 140 may thus be in sync with laser beam delivery system 130 so that the optical surface profiler 140 can instantaneously measure the surface profile at the laser processing spot (the location where the dielectric material is to be ablated and the dielectric layer planarized) and provide feedback to a controller 150 to adjust the laser conditions if desired and indicate whether ablation is to terminate. In-situ monitoring may be used, for example, when no calibration occurs prior to ablation or when the calibration provides a rough estimate or is otherwise in error. In some embodiments, in-situ monitoring may not be performed. The optical surface profiler 140 may measure, in a well-known manner, the amount of radiation from the emitter 142 received by the receiver 144 or the scatter. The optical surface profiler 140 may provide topography specifics equal to or larger than the size of the laser to permit the laser to remove the indicated material with precision.

A feedback loop control system (controller) 150 may be used to control the laser beam delivery unit 130 to steer the laser beam 120. The controller 150 may also control movement of the stage 110. In some cases, the Galvano scanner system 132 may have a limited range of movement (e.g., about 30 mm×30 mm), thus the controller 150 may control the Galvano scanner system 132 to move up to the limited range of the Galvano scanner system 132 and subsequently move the stage 110, which may have a much larger range of motion. Note that although the Galvano scanner system 132 is described as being able to be repositioned under the control of the controller 150, the laser beam delivery unit 130 may be stationary and only the stage 110 movable or both may be adjustable.

The controller 150 may thus link the optical surface profiler 140, the laser beam delivery unit 130 and the laser control unit of the laser 120 together for real-time processing control. The controller 150 may control each piece of equipment and, based on information from the optical surface profiler 140, produce the desired planarization of the dielectric layer being planarized.

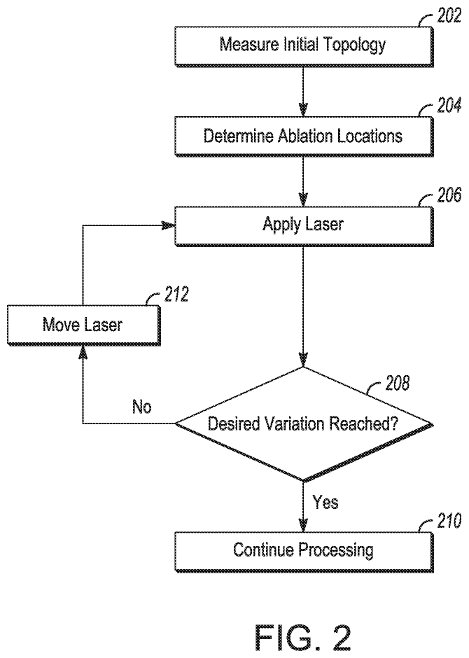

FIG. 2 illustrates a method of planarization in accordance with some embodiments. The method may use the equipment shown in FIG. 1, although additional equipment may also be used. A processor in the controller that executes instructions stored in a memory of the controller may configure the controller to undertake operations controlled by the controller. After placing the panel on the stage and attaching the panel securely, at operation 202 the surface profiler may be used to measure the initial topology (thickness variations) of the panel. The initial topology may be that of the initial organic substrate, the dielectric layer deposited before the HA (which has not been deposited) or any other layer therebetween. In some embodiments, metallization layers may be planarized by the laser process in addition to the dielectric layers.

To determine the topology, the surface profiler may emit light from the emitter, receive the scattered light at the receiver and send data to a processor, which may be internal to the surface profiler or may be part of the controller. The processor may take the raw data, e.g., of the amount of scattered light, and determines the thickness of the layer at the position. The data from the surface profiler may include the position when transmitting the data or the position may be maintained by the processor, with only the data being provided to the processor from the surface profiler. After the measurement has been taken, the controller may advance the stage by the resolution of the surface profiler to a new position for measurement. The measurements may occur until measurements have been taken over the entire region of interest and a topography profile (or map) determined accordingly. Although the entire region of interest may be the entire panel, there may be circumstances in which this region may be less than the entire panel—for example a known region of high variation that is problematic.

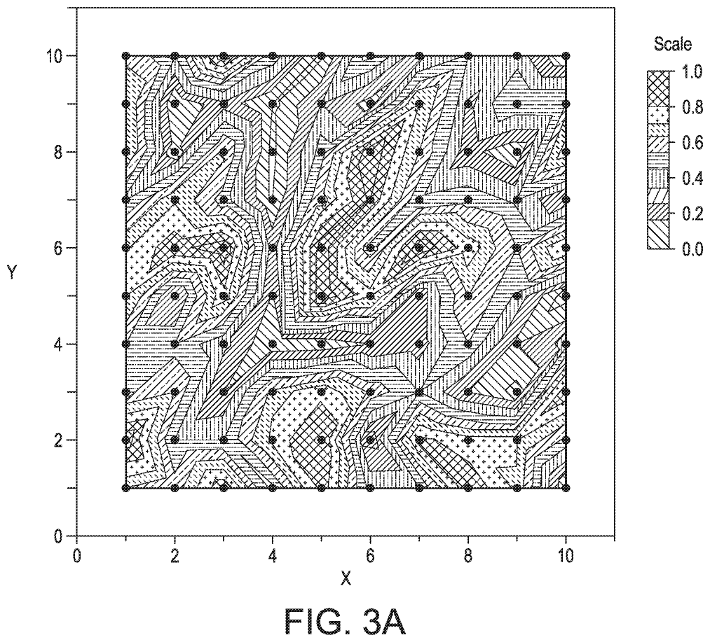

The data and position may be translated into a topography profile of the dielectric (organic) layer from a predefined reference plane. FIG. 3A illustrates a dielectric topography profile in accordance with some embodiments. The obtained profile may subsequently be digitized into discrete blocks. In some embodiments, the blocks may be of a uniform size. The size of blocks may depend on the profile variation across the entire panel and planarization specification (a range of how much remaining variation across the entire panel is acceptable after planarization). The size of the blocks may be further limited by the mechanical aspects of the system (e.g., the spot size of the laser or the minimum step size of the laser beam delivery unit and possibly the stage). Alternatively, the block size may be based on the smallest topographical feature. In some embodiments, the block size may vary dependent on the topographical variation across the panel, for example, the block size may be larger where the topographical variation remains constant and smaller where the variation Changes rapidly. FIG. 3B illustrates a digitization of the dielectric topography profile of FIG. 3A in accordance with some embodiments. FIG. 3B shows an embodiment in which the blocks are of uniform size.

In some embodiments, the controller may correlate each block with and assign to a corresponding laser process condition. The laser process conditions may be determined via calibration of removal by the laser of the dielectric prior to planarization. The laser calibration may be performed, for example, on a separate (dummy) panel of dielectric material prior to planarizing the panel. For example, the laser may be calibrated to determine the specifics (e.g., fluence/power, time) for the laser to remove a predetermined amount of the dielectric material. This predetermined amount of dielectric material may be, for example, a proportion e.g., 10%, 20%, 25%, 50%, 100%) of the maximum threshold variation desired.

The block types of FIG. 3B may be discriminated by the maximum number of height differences. For example, the number of block types may be the total variation divided by the above calibrated amount of dielectric material removed during a single predetermined time period (or multiple time periods). The number of block types may, in other embodiments, be independent of the maximum number of height differences and may be a preset number (e.g., 8, 16 or 32). The calibration information may be stored in a memory associated with the controller, along with the topography data and position and the corresponding laser process condition. In other embodiments, only the topography map or corresponding digitization may be stored, with the controller relying on in-situ feedback to adjust the laser conditions. Thus, although the ablation rate or removal rate may be calibrated for each material being removed by the laser, in-situ monitoring permits dynamic measurement of the surface profile. This measured profile can be used to determine how much more material to remove and can also be used to calculate how much was removed by comparing the amount to the previously saved profile.

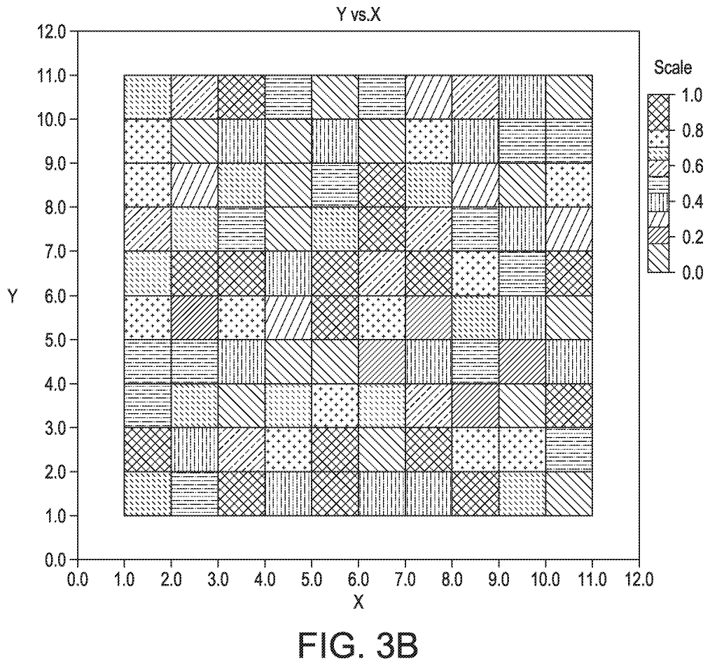

At operation 204, the controller may determine the ablation locations based on the stored information. In some embodiments, a slicing-like approach may be used as shown in FIGS. 4A-4D, in which the panel is logically divided into multiple areas, each area is laser sliced individually, with the laser being moved back and forth across the area and repeatedly “slicing oft” a predetermined amount each pass. FIG. 4A illustrates the substrate before planarization, while FIGS. 4B and 4C illustrate the substrate during planarization and FIG. 4D illustrates the substrate after planarization. In other embodiments, the laser may remain steadily in a single desired location to ablate the material at that location. In this case, the controller may determine a first position to planarize. The position may be a predetermined starting block of the panel, such as the upper left hand corner. The controller may move the laser to the first of the position(s) so determined using one or both of the laser beam delivery unit and the stage. During movement, an iris of the laser beam delivery unit may be closed to avoid inadvertent removal of dielectric material while the laser beam is being moved to the desired location.

Alternatively, the controller may determine the position(s) with the greatest amount of material (i.e., the position that is highest/has the largest variance) within a predetermined variance. For example, if the thickness of the dielectric material varies over the panel from <10 μm from the reference plane to 100 μm from the reference plane, the controller may determine locations within one calibration time period. The controller may move to a first of the position(s) determined.

At operation 2016, the controller may indicate to the laser beam delivery unit to open the iris and apply the laser to the instant position. The laser fluence used during calibration may be supplied for one or multiple time periods corresponding to the predetermined amount of material. In some embodiments, the laser beam may be controlled to move across the area to slice the dielectric material as shown in FIGS. 4B-4D, The optical surface profiler may be used during removal for in-situ monitoring and an instantaneous feedback to the controller to confirm that the calculated amount of dielectric material has been removed and thus control removal to sub-micron resolution.

In other embodiments, the above calibration process may not be performed. In this case, the surface profile may be dynamically monitored to instantaneously adjust the laser conditions to account for the amount of material to be removed to reach the desired planarization target. Thus, the laser power, pulse energy and/or fluence can be adjusted, as can the beam size. Adjustment of beam size can be done instantaneously by adjusting the iris.

Once the desired amount of material is removed at the first location as shown in FIG. 4B, the controller at operation 208, may determine whether the desired thickness variation has been reached for all blocks in the panel or the area of the panel being planarized if less than all of the panel is being planarized.

If the desired thickness variation has been determined to have been reached at operation 208, the controller may at operation 210 reset the laser beam delivery unit and the stage to an initial position, remove the vacuum to permit the panel to be manually moved, and/or pass control to other equipment for further processing of the panel (or otherwise provide an alert that planarization is completed). The controller may perform this after the final dielectric layer to be planarized is planarized. This may be the dielectric layer immediately under the FLI or a dielectric layer several layers under the FLI.

If the controller at operation 208 determines that another block is to be planarized, the controller at operation 212 may move the laser beam delivery unit to the next block to be planarized. Prior to moving the laser beam, the controller may control the laser beam delivery unit to close the iris. The next block may be adjacent to the instant area or may be anywhere within the panel dependent on the topology of the panel. As above, the controller may then move the laser beam to the other block using one or both of the laser beam delivery unit and the stage. The laser beam may be used as above to planarize the new block as shown in FIG. 4C. This process may be repeated as shown in FIG. 4D.

FIGS. 4A-4D thus illustrate a cross-sectional view of a method of planarization according to some embodiments. A simplified surface of the panel is shown before and after planarization of each block of N blocks. As the heights are different, the laser conditions used may vary. Note that, as indicated above, the method may be limited to not apply planarization to the entire panel (unlike CMP). This is to say that, in some embodiments, planarization may be limited by the controller to only those blocks whose thickness exceeds the thickness variation. Once thickness variation is met for all blocks, the process may be terminated for a particular layer.

Planarization may also be dependent on the dielectric layer. For example, the maximum thickness variation (and thus amount of planarization) may change between dielectric layers. In some embodiments, the amount of thickness variation may decrease with distance from the FLI. That is, dielectric layers that are to be closer to the HA may tolerate less thickness variation than those buried deeper. Thus, layers buried further into the panel may planarize only topographical features that have a height above the average variation (or perhaps the top 10 or 20% of height, for example).

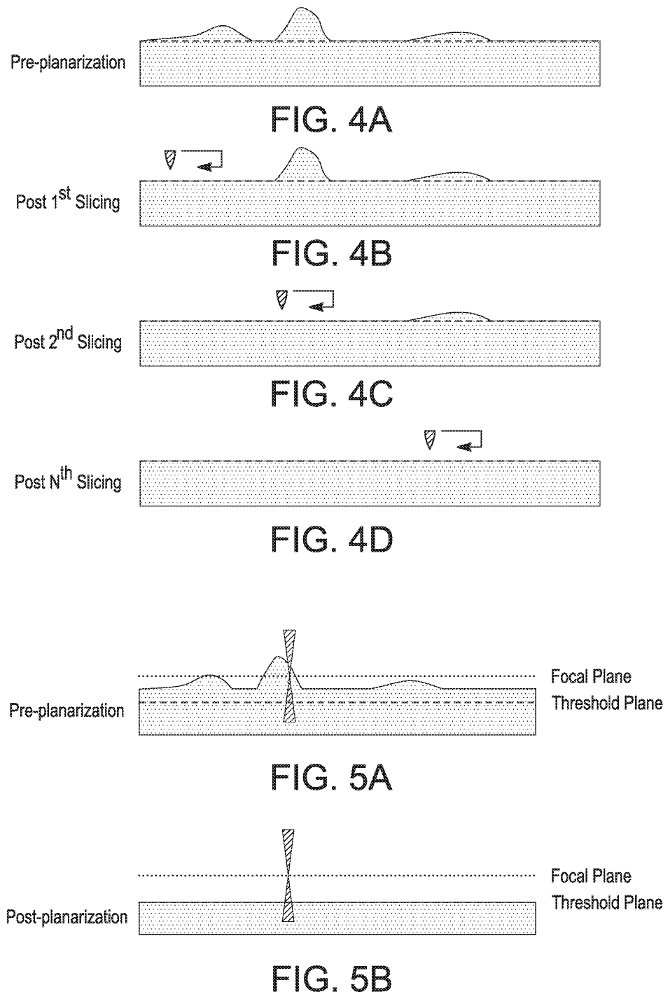

In other embodiments, rather than using the technique shown in FIGS. 4A-4D, the effects of laser focusing may be used for universal planarization. FIGS. 5A-5B illustrate a cross-sectional view of another method of planarization according to some embodiments. In this method, the topography profile may also be scanned prior to ablation in a manner similar to the above to determine the amount of dielectric material to be planarized for each block. For laser processing, especially photochemical ablation, material may not be ablated until the laser fluence exceeds an ablation threshold of the material. Laser fluence is inversely proportional to the square of the beam size. For a focused beam, the laser beam size diverges quickly as the beam extends beyond the focal depth. The focal depth may be controlled by the focusing optical system in the laser beam delivery unit. Thus, the fluence decreases commensurately with the depth as well.

When the laser fluence drops below the ablation threshold, no material will be ablated. Based on topography profile scan taken initially by the optical surface profiler 140, the peaks and valleys can be determined before planarization. The beam focus may be set at a predefined focal plane as shown in FIG. 5A. At certain offset from this plane (shown as the threshold plane in FIG. 5A), the laser fluence drops below threshold and automatically stop the planarization process. By scanning the laser beam across the entire panel with this fixed focal position, a flat panel surface can be obtained as shown in FIG. 5B. This may reduce the amount of processing the controller is to perform.

In some embodiments, to enhance the focus effects, a thin metal layer (e.g., of less than about 100 μm) can be deposited on the panel before initiating the planarization process. Sputtering or plating may be used to deposit the metal, which may be copper (Cu) or aluminum (Al), for example. As metal has higher ablation threshold compared to an organic-based dielectric material, the focal effect is more significant on metal. In this embodiment, when the metal layer is not ablated, the dielectric material underneath the metal may remain intact. Only those parts of the panel within the focal depth that can deliver enough fluence, may initially remove the metal layer, and then thereafter ablate the dielectric material below.

In this process, in-situ process monitoring can be enabled to adjust the ablation conditions. The in-situ monitoring may be used to determine when the metal layer is fully ablated and the laser condition adjusted by the controller to reduce the laser power or fluence, for example, for the dielectric layer. In other embodiments, the laser conditions for the metal layer and dielectric layers may be the same. The remaining metal layer may, in some embodiments, be removed after planarization.

FIGS. 6A-6D illustrate cross-sectional views of another method of planarization according to some embodiments. This method of planarization is similar to the method shown in FIGS. 4A-4D, in which the laser slices through the peak in a single location at a time. However, in the embodiment shown in FIGS. 4A-4D, the laser is used to remove the excess material in each location, thereby planarizing the material at that location, before moving to the next location. Although the starting and ending points are the same in the embodiments of FIGS. 4A-4D and FIGS. 6A-6D (i.e., the pre-planarization in FIG. 4A/6A and planarized surface in FIG. 4D/6D), as shown in FIGS. 6B and 6C, the planarization process is somewhat different.

A slicing-like approach may be used during planarization in FIGS. 6A-6D, the panel being logically divided into multiple areas. The optical surface profiler may be used prior to planarization to initially determine the entire panel profile. The optical surface profiler may also be when a particular area is reached for in-situ monitoring and an instantaneous feedback to the controller. The controller may store the variation at each location. Rather than the laser being moved across a particular area and repeatedly slicing off a predetermined amount each pass to planarize that area before moving to the next area, as shown in FIGS. 6B and 6C, the laser is repeatedly scanned across the entire panel to be planarized without stopping or repeating over a particular area during a single scan.

In this case, the laser power may dynamically change depending on the locations of the peaks as the laser is moved across the panel. In particular, the controller may set a reference height from a reference plane (planarization plane) and determine from the stored information of the optical surface profiler when an area of the greatest remaining variation (i.e., the reference height) has been reached during a scan and may either indicate to the laser beam delivery unit to open the iris and apply the laser to the area, or increase the power of the laser to a power sufficient to remove material from a power insufficient to remove the material. Each area having a peak of the same size (within a predetermined range) may have a predetermined amount sliced off in the same scan using the same laser power at each area. This may thus reduce all peaks of the same height (i.e., above a reference height) in the panel over a single scan as shown in FIG. 6B.

After the first scan, a new panel profile may be generated by a topography measurement using the optical surface profiler. A new reference height that is lower than the original reference height may be set, and a second slicing scan may remove material above the new reference height as shown in FIG. 6C, including material from several different peaks. The amount of material removed by each scan may be the same or may be different. The former embodiment may simplify processing constraints by incrementing the reference height by the same amount towards the final planarization reference height (or final planarization target). The latter embodiment may speed the planarization, for example, by changing the reference height (and thus laser power) depending on the difference between the highest peaks and the next highest peaks as determined by the last topographical measurement. This is to say that if a first set adjacent set of peaks differs dramatically in height while a second set of adjacent set of peaks differs relatively little in height, the laser power for the first set may be higher than that for the second set to remove more material during the scan to remove more material during the scan for the first set than for the second set. Regardless of whether the same power or different power is used for different scans however, a final planarization target (e.g., the reference plane) may be obtained after several iterations as shown in FIG. 6D.

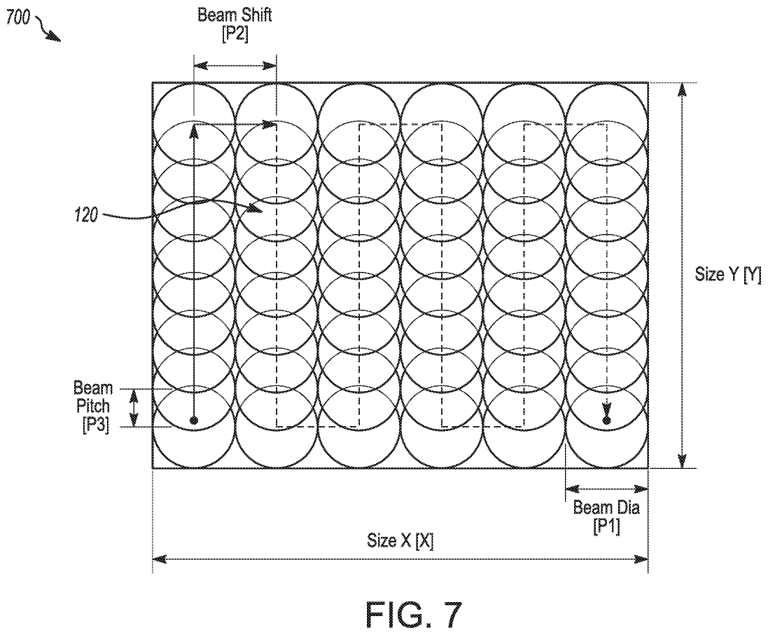

FIG. 7 illustrates a method of planarization in accordance with some embodiments. The method may use the equipment shown in FIG. 1, although additional equipment may also be used. After placing the panel on the stage and attaching the panel securely, at operation 702 the surface profiler may be used to measure the initial topography of the panel. The topography profile of the layer from a predefined reference plane may be digitized into discrete blocks and each block assign a corresponding laser process condition.

At operation 704, the processor may determine the ablation locations based on the stored information. As above, a slicing-like approach may be used. The controller may determine the position(s) with the greatest amount of material (i.e., the position that is highest/has the largest variance) within a predetermined variance. For example, if the thickness of the dielectric material varies over the panel from <10 μm from the reference plane to >100 μm from the reference plane, the controller may determine locations within one calibration time period. The controller may then move the laser to the first of the position(s) so determined using one or both of the laser beam delivery unit and the stage. During movement, an iris of the laser beam delivery unit may be closed to avoid inadvertent removal of dielectric material while the laser is being moved to the desired location.

At operation 706, the controller may indicate to the laser beam delivery unit to open the iris and apply the laser to the first of the position(s). The laser fluence used during calibration may be supplied for one or multiple time periods corresponding to the predetermined amount of material. The optical surface profiler may be used during removal for in-situ monitoring and an instantaneous feedback to the controller to confirm that the calculated amount of dielectric material has been removed. The feedback may indicate to the controller, for example, to reduce the laser power/fluence/pulse energy to slow down the rate of removal after a predetermined portion of the variation has been removed or when the variation reaches a predetermined threshold near the desired level of planarization (e.g., as the variation is reduced to about 10% or 20% more than the desired level of planarization).

Once the desired amount of material is removed at the first location, the controller at operation 708, may determine whether the panel contains another position having the same height (the same amount of dielectric material) as the first position originally had. As above, the controller may consider the positions to be the same height if within a differential threshold—e.g., an amount of dielectric material removed in a single time period.

If the controller at operation 708 determines that another position of the same height is present, the controller at operation 710 may control the laser beam delivery unit to close the iris and then move to the other position. This position may be anywhere within the panel. As above, the controller may then move the laser to the other position using one or both of the laser beam delivery unit and the stage.

If the controller at operation 708 determines that no other position of the same height is present, the controller at operation 712 may determine whether the desired thickness variation has been reached for all positions in the panel (or area of the panel being planarized). As above, the desired thickness variation may be one or more times the predetermined amount of dielectric material removed during a single time period.

If the desired thickness variation has been determined to have been reached at operation 712, further processing after planarization may occur in the manner indicated above. Thus, further layers may be deposited and patterned, for example.

If the desired thickness variation has been determined to have been reached at operation 712, the controller may at operation 716 initiate another topographical scan to measure the new topography profile of the panel. The topographical scan may be used, for example, when multiple locations on the panel have been subject to the laser ablation (planarization) and the topography near the planarized areas may have inadvertently been affected. The new topographical map (and calculations thereof) may be used to replace the initial topographical map. In some embodiments, the new topographical map may be determined after every set of positions of the same height are removed. In other embodiments, the new topographical map may be determined after a predetermined number of different positions have been planarized.

Independent of the method of laser planarization used, planarization may also be dependent on the dielectric layer. For example, the maximum thickness variation (and thus amount of planarization) may change between dielectric layers. In some embodiments, the amount of thickness variation may decrease with distance from the FLI. That is, dielectric layers that are to be closer to the FLI may tolerate less thickness variation than those buried deeper. Thus, layers buried further into the panel may planarize only topographical features that have a height above the average variation (or perhaps the top 10 or 20% of height, for example).

As above, the laser beam may operate in the optical or UV range, depending on, for example, feature size on the panel. For example, a UV laser source may be used to skive a panel with dielectric material (e.g., Ajinomoto Build-up Film (ABF) GY50) laminated thereon. Different processing conditions such as laser beam size and beam overlapping were tested on a test panel prior to use on a panel. The laser beam was skived along the surface of the panel. FIG. 6 illustrates skiving in accordance with some embodiments. As shown in FIG. 6, the post-skiving surface Ra/line Ra was measured. An example of the skiving parameters is listed as below in Table 1. An Ra as small as 0.3 μm was obtained in skived area.

TABLE 1
Experimental parameter and post laser planarization Ra

| Laser beam diameter | P2 | P3 | Line Ra. |
|---|---|---|---|
| (μm) | (μm) | (μm) | (μm) |
| 20 | 3 | 6 | 0.3 |

The laser ablation rate was calibrated on ABF with 355 nm nanosecond laser. With fluence of 0.72 J/cm2, ablation rate of 0.9 urn/pulse is achieved on GY50 ABF with a 20 μm laser beam. With this reference value, the planarization run rate is estimated as below.

TABLE 2
Planarization run rate calculation

| | | | ref. ablation rate | | ABF | |
|---|---|---|---|---|---|---|
| pulse | rep | avg. | (μm/pulse) @ | Planarization | thick- | Processing |
| energy (mJ) | rate(Hz) | power(W) | 0.72 J/cm2 | area (mm2) | ness (μm) | time (min) |
| 0.2 | 200000 | 40 | 0.9 | 480 × 480 | 10 | 7.4 |

As shown in Table 2, a 355 nm UV laser with average power of 40 W was used for a run rate calculation. The laser was operated at 200 kHz. Assuming a 10 μm ABF is to be removed over 50% of the active area of a panel of 480 mm×480 mm, the processing time is 7.4 min. By utilizing a higher power laser such as 200 W, the laser beam may be split into, for example, 4 laser heads by one or more splitters and sent to different laser beam delivery units that permit the laser to impinge on different panels on different stages. This may permit 4 panels to be processed within same time, which leads to run rate of 32 panels per hour. The same controller or different controllers may control each laser beam delivery unit and stage. In one example, the total processing time=Planarized material volume/(average power*0.9 μm*0.72 cm²/J).

For a selective planarization method, the run rate can be further improved since only a portion of the entire panel may be planarized. The current CMP run rate is about 10-20 min per panel depending on the planarization depth. Laser planarization takes about 15 min to thin down 20 μm material, thereby improving the planarization run rate over CMP,

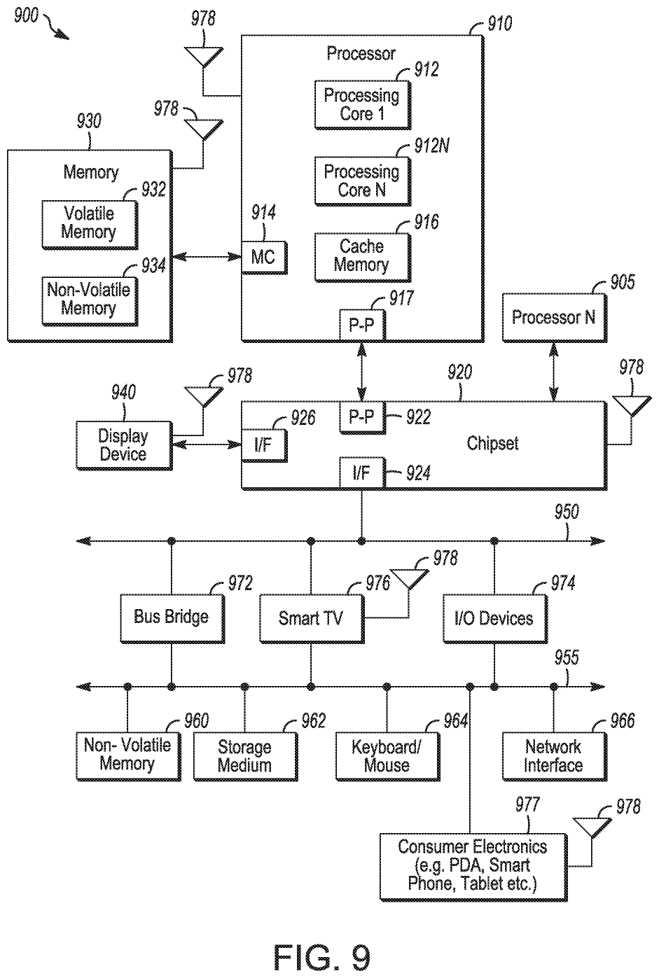

FIG. 9 illustrates a system level diagram for devices associated with the laser planarization process by the methods described herein. Some or all of the devices shown in FIG. 9 may have been fabricated by the laser planarization process, or may been used to form the structure described in one or more of the above embodiments. In one embodiment, system 900 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 900 is a system on a chip (SOC) system.

In one embodiment, processor 910 has one or more processor cores 912 and 912N, where 912N represents the Nth processor core inside processor 910 where N is a positive integer. In one embodiment, system 900 includes multiple processors including 910 and 905, where processor 905 has logic similar or identical to the logic of processor 910. In some embodiments, processing core 912 includes, but is not limited to, pre-fetch logic to fetch instructions, decode logic to decode the instructions, execution logic to execute instructions and the like. In some embodiments, processor 910 has a cache memory 916 to cache instructions and/or data for system 900. Cache memory 916 may be organized into a hierarchal structure including one or more levels of cache memory.

In some embodiments, processor 910 includes a memory controller 914, which is operable to perform functions that enable the processor 910 to access and communicate with memory 930 that includes a volatile memory 932 and/or a non-volatile memory 934. In some embodiments, processor 910 is coupled with memory 930 and chipset 920. Processor 910 may also be coupled to a wireless antenna 978 to communicate with any device configured to transmit and/or receive wireless signals. In one embodiment, an interface for wireless antenna 978 operates in accordance with the 3GPP and/or IEEE 802.11 standard protocol, Home Plug AV (HPAV), Ultra Wide Band (UWB), Bluetooth, WiMax, or any form of wireless communication protocol.

In some embodiments, volatile memory 932 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 934 includes, but is not limited to, flash memory, phase change memory (PCM), read-only memory (ROM), electrically erasable programmable read-only memory (EEPROM), or any other type of non-volatile memory device.

Memory 930 stores information and instructions to be executed by processor 910, in one embodiment, memory 930 may also store temporary variables or other intermediate information while processor 910 is executing instructions. In the illustrated embodiment, chipset 920 connects with processor 910 via Point-to-Point (PtP or P-P) interfaces 917 and 922. Chipset 920 enables processor 910 to connect to other elements in system 900. In some embodiments of the example system, interfaces 917 and 922 operate in accordance with a PtP communication protocol such as the Intel® QuickPath Interconnect (QPI) or the like. In other embodiments, a different interconnect may be used.

In some embodiments, chipset 920 is operable to communicate with processor 910, 905N, display device 940, and other devices, including a bus bridge 972, a smart TV 976, I/O devices 974, nonvolatile memory 960, a storage medium (such as one or more mass storage devices) 962, a keyboard/mouse 964, a network interface 966, and various forms of consumer electronics 977 (such as a PDA, smart phone, tablet etc.), etc. In one embodiment, chipset 920 couples with these devices through an interface 924. Chipset 920 may also be coupled to a wireless antenna 978 to communicate with any device configured to transmit and/or receive wireless signals.

Chipset 920 connects to display device 940 via interface 926. Display 940 may be, for example, a liquid crystal display (LCD), a light emitting diode (LED) array, an organic light emitting diode (OLED) array, or any other form of visual display device. In some embodiments of the example system, processor 910 and chipset 920 are merged into a single SOC. In addition, chipset 920 connects to one or more buses 950 and 955 that interconnect various system elements, such as I/O devices 974, nonvolatile memory 960, storage medium 962, a keyboard/mouse 964, and network interface 966. Buses 950 and 955 may be interconnected together via a bus bridge 972.

In one embodiment, mass storage device 962 includes, but is not limited to, a solid state drive, a hard disk drive, a universal serial bus flash memory drive, or any other form of computer data storage medium. In one embodiment, network interface 966 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the 3GPP standard and its related family, the IEEE 802.11 standard and its related family, Home Plug AV (HPAV), Ultra Wide Band (UVB), Bluetooth, WiMax, or any form of wireless communication protocol.

While the modules shown in FIG. 9 are depicted as separate blocks within the system 900, the functions performed by some of these blocks may be integrated within a single semiconductor circuit or may be implemented using two or more separate integrated circuits. For example, although cache memory 916 is depicted as a separate block within processor 910, cache memory 916 (or selected aspects of 916) can be incorporated into processor core 912.

### Additional Notes and Examples

Example 1 is a planarization method, the method comprising: moving, by an electronic controller, a laser beam across a layer to be planarized, the laser beam being moved to each of planarization blocks that contain material to be removed; and for each planarization block, removing, by the laser beam, the material based on predetermined laser conditions to planarize a portion of the layer corresponding to the planarization block.

In Example 2, the subject matter of Example 1 includes, wherein: moving the laser beam comprises the controller steering a laser beam delivery unit on which the laser beam impinges to steer the laser beam to the planarization block of the material to be removed, and the laser beam delivery unit comprises a scanner system to steer the laser beam over the layer.

In Example 3, the subject matter of Example 2 includes, retaining the layer on a movable stage, planarization of the layer performed by steering the laser beam without moving the stage.

In Example 4, the subject matter of Examples 2-3 includes, wherein: the laser beam delivery unit further comprises a focusing optical system to focus the laser beam on the planarization block at a focal plane and to have a focal depth beyond which no material is ablated.

In Example 5, the subject matter of Example 4 includes, wherein: moving the laser beam further comprises steering the laser beam across an entire surface of the layer.

In Example 6, the subject matter of Examples 4-5 includes, depositing a thin metal layer over the layer to be planarized, the layer to be planarized being formed from a dielectric and having a lower ablation threshold than the metal layer, the material to be removed at the planarization block ablated by the laser beam after ablation by the laser beam of the metal layer at the planarization block.

In Example 7, the subject matter of Example 6 includes, providing in-situ monitoring of a surface profile at the planarization block to provide feedback to the controller; and adjusting, by the controller, the laser conditions for the planarization block after ablation of the metal layer for ablation of the material to be removed.

In Example 8, the subject matter of Examples 1-7 includes, digitizing, by a processor, a topographic map of the layer into blocks of different types, each type of block corresponding to a different amount of material to be removed to planarize the layer; and assigning, by the processor, the laser conditions to each of the blocks dependent on the amount of material to be removed.

In Example 9, the subject matter of Example 8 includes, measuring, using an optical surface profiler, topography of the layer to be planarized to produce the topographic map of the layer, the optical surface profiler comprising a light emitter and receiver disposed at an acute angle to the layer.

In Example 10, the subject matter of Example 9 includes, providing in-situ monitoring of a surface profile at the planarization block to provide feedback to the controller, the controller coupled with the optical surface profiler, the laser beam delivery unit, and a laser control unit to adjust the laser conditions for the planarization block to planarize the planarization block.

In Example 11, the subject matter of Examples 8-10 includes, wherein the blocks are of uniform size that is dependent on a variation of a profile across the layer and a planarization specification of how much variation across the layer after planarization is acceptable.

In Example 12, the subject matter of Examples 8-11 includes, setting a reference height from a reference plane; scanning across the layer to each block having material above the reference height and removing the material above the reference height; and after completing a scan of the layer, repeating the setting, scanning, and removing using consecutively lower reference heights until the layer is free from material above the reference plane.

In Example 13, the subject matter of Examples 8-12 includes, calibrating the laser beam on a same type of material to be planarized prior to planarizing the layer to determine the laser conditions to remove an amount of material corresponding to each type of block.

In Example 14, the subject matter of Examples 1-13 includes, limiting locations of planarization on the layer to the planarization blocks.

Example 15 is a system for planarizing a layer of a multilayer electronic panel, the system comprising: an optical surface profiler configured to map topography of the dielectric layer to produce a topographic map of the dielectric layer, the optical surface profiler comprising a light emitter and receiver each disposed at an acute angle to the layer; a laser beam delivery unit comprising a scanner system configured to steer a laser beam that impinges thereon; and a controller comprising a processor configured to: digitize the topographic map into blocks of different types, each type of block corresponding to a different amount of material to be removed to planarize the dielectric layer, assign laser conditions to each of the blocks dependent on an amount of material to be removed at the block, control the scanner system of the laser beam delivery unit to steer the laser beam to planarization blocks having material to be ablated, and planarize the dielectric layer by controlling removal of the material at each planarization block based on the laser conditions.

In Example 16, the subject matter of Example 15 includes, a movable stage configured to retain the panel thereon via a vacuum chuck during planarization, wherein the stage remains stationary during planarization of the layer.

In Example 17, the subject matter of Examples 15-16 includes, wherein: the laser beam delivery unit further comprises a focusing optical system to focus the laser beam on the planarization block at a focal plane and to have a focal depth beyond which no material is ablated, and the controller is further configured to control the scanner system of the laser beam delivery unit to steer the laser beam across an entire surface of the dielectric layer.

In Example 18, the subject matter of Example 17 includes, wherein: a thin metal layer is deposited over the dielectric layer, the metal layer has a higher ablation threshold than the dielectric layer, the optical surface profiler is further configured to provide in-situ monitoring of a surface profile during planarization to provide feedback to the controller, and the controller is further configured to adjust the laser conditions after ablation of the metal layer for ablation of the material to be removed.

Example 19 is a computer-readable storage medium that stores instructions for execution by one or more processors of a controller, the one or more processors to configure the controller to, when the instructions are executed: digitize a topographic map of a dielectric layer into blocks of different types, each type of block corresponding to a different amount of dielectric material to be removed to planarize the dielectric layer; assign laser conditions to each of the blocks dependent on the amount of material to be removed; steer a laser beam to each of planarization blocks that contain material to be removed; and control ablation of the dielectric material by the laser beam based on the laser conditions and in-situ measurements of a surface of the dielectric layer being planarized.

In Example 20, the subject matter of Example 19 includes, wherein: a thin metal layer is deposited over the dielectric layer, the metal layer has a higher ablation threshold than the dielectric layer, and the instructions, when executed, further configure the controller to: focus the laser beam at a focal plane and to have a focal depth beyond which no material is ablated, and adjust the laser conditions after ablation of the metal layer for ablation of the dielectric material.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

1. A planarization method, the method comprising:
moving, by an electronic controller, a laser beam across a layer to be planarized, the laser beam being moved to each of planarization blocks that contain material to be removed; and
for each planarization block, removing, by the laser beam, the material based on predetermined laser conditions to planarize a portion of the layer corresponding to the planarization block.

2. The method of claim 1, wherein:
moving the laser beam comprises the controller steering a laser beam delivery unit on which the laser beam impinges to steer the laser beam to the planarization block of the material to be removed, and
the laser beam delivery unit comprises a scanner system to steer the laser beam over the layer.

3. The method of claim 2, further comprising retaining the layer on a movable stage, planarization of the layer performed by steering the laser beam without moving the stage.

4. The method of claim 2, wherein:
the laser beam delivery unit further comprises a focusing optical system to focus the laser beam on the planarization block at a focal plane and to have a focal depth beyond which no material is ablated.

5. The method of claim 4, wherein:
moving the laser beam further comprises steering the laser beam across an entire surface of the layer.

6. The method of claim 4, further comprising:
depositing a thin metal layer over the layer to be planarized, the layer to be planarized being formed from a dielectric and having a lower ablation threshold than the metal layer, the material to be removed at the planarization block ablated by the laser beam after ablation by the laser beam of the metal layer at the planarization block.

7. The method of claim 6, further comprising:
providing in-situ monitoring of a surface profile at the planarization block to provide feedback to the controller; and
adjusting, by the controller, the laser conditions for the planarization block after ablation of the metal layer for ablation of the material to be removed.

8. The method of claim 1, further comprising:
digitizing, by a processor, a topographic map of the layer into blocks of different types, each type of block corresponding to a different amount of material to be removed to planarize the layer; and
assigning, by the processor, the laser conditions to each of the blocks dependent on the amount of material to be removed.

9. The method of claim 8, further comprising measuring, using an optical surface profiler, topography of the layer to be planarized to produce the topographic map of the layer, the optical surface profiler comprising a light emitter and receiver disposed at an acute angle to the layer.

10. The method of claim 9, further comprising providing in-situ monitoring of a surface profile at the planarization block to provide feedback to the controller, the controller coupled with the optical surface profiler, the laser beam delivery unit, and a laser control unit to adjust the laser conditions for the planarization block to planarize the planarization block.

11. The method of claim 8, wherein the blocks are of uniform size that is dependent on a variation of a profile across the layer and a planarization specification of how much variation across the layer after planarization is acceptable.

12. The method of claim 8, further comprising:
setting a reference height from a reference plane;
scanning across the layer to each block having material above the reference height and removing the material above the reference height; and
after completing a scan of the layer, repeating the setting, scanning, and removing using consecutively lower reference heights until the layer is free from material above the reference plane.

13. The method of claim 8, further comprising:
calibrating the laser beam on a same type of material to be planarized prior to planarizing the layer to determine the laser conditions to remove an amount of material corresponding to each type of block.

14. The method of claim 1, further comprising limiting locations of planarization on the layer to the planarization blocks.

15. A system for planarizing a layer of a multilayer electronic panel, the system comprising:
an optical surface profiler configured to map topography of the dielectric layer to produce a topographic map of the dielectric layer, the optical surface profiler comprising a light emitter and receiver each disposed at an acute angle to the layer;
a laser beam delivery unit comprising a scanner system configured to steer a laser beam that impinges thereon; and
a controller comprising a processor configured to:
digitize the topographic map into blocks of different types, each type of block corresponding to a different amount of material to be removed to planarize the dielectric layer,
assign laser conditions to each of the blocks dependent on an amount of material to be removed at the block,
control the scanner system of the laser beam delivery unit to steer the laser beam to planarization blocks having material to be ablated, and
planarize the dielectric layer by controlling removal of the material at each planarization block based on the laser conditions.

16. The system of claim 15, further comprising a movable stage configured to retain the panel thereon via a vacuum chuck during planarization, wherein the stage remains stationary during planarization of the layer.

17. The system of claim 15, wherein:
the laser beam delivery unit further comprises a focusing optical system to focus the laser beam on the planarization block at a focal plane and to have a focal depth beyond which no material is ablated, and
the controller is further configured to control the scanner system of the laser beam delivery unit to steer the laser beam across an entire surface of the dielectric layer.

18. The system of claim 17, wherein:
a thin metal layer is deposited over the dielectric layer,
the metal layer has a higher ablation threshold than the dielectric layer, the optical surface profiler is further configured to provide in-situ monitoring of a surface profile during planarization to provide feedback to the controller, and
the controller is further configured to adjust the laser conditions after ablation of the metal layer for ablation of the material to be removed.

19. A computer-readable storage medium that stores instructions for execution by one or more processors of a controller, the one or more processors to configure the controller to, when the instructions are executed:
digitize a topographic map of a dielectric layer into blocks of different types, each type of block corresponding to a different amount of dielectric material to be removed to planarize the dielectric layer;
assign laser conditions to each of the blocks dependent on the amount of material to be removed;
steer a laser beam to each of planarization blocks that contain material to be removed; and
control ablation of the dielectric material by the laser beam based on the laser conditions and in-situ measurements of a surface of the dielectric layer being planarized.

20. The medium of claim 19, wherein:
a thin metal layer is deposited over the dielectric layer,
the metal layer has a higher ablation threshold than the dielectric layer, and
the instructions, when executed, further configure the controller to:
focus the laser beam at a focal plane and to have a focal depth beyond which no material is ablated, and
adjust the laser conditions after ablation of the metal layer for ablation of the dielectric material.
